(19) United States
(12) Patent Application Publication
(10) Pub. No.: US 2026/0026048 A1
(43) Pub. Date: Jan. 22, 2026

(54) GATE-ALL-AROUND DEVICES AND MANUFACTURING METHOD THEREOF

(71) Applicant: Taiwan Semiconductor Manufacturing Company, Ltd., Hsin-Chu (TW)

(72) Inventors: Chia-Hung CHOU, Hsinchu (TW); Ka-Hing FUNG, Hsinchu County (TW)

(21) Appl. No.: 18/962,326

(22) Filed: Nov. 27, 2024

Related U.S. Application Data
(60) Provisional application No. 63/672,579, filed on Jul. 17, 2024.

(51) Int. Cl. H01L 29/786; H01L 29/06; H01L 29/423; H01L 29/66; H01L 29/775

(52) U.S. Cl. CPC H10D 30/6757; H10D 30/014; H10D 30/43; H10D 30/6735; H10D 30/6741; H10D 62/121; H10D 64/017; H10D 64/018

(57) ABSTRACT

A method of the present disclosure includes forming a stack that includes channel layers interleaved by sacrificial layers, patterning the stack to form a fin-shaped structure, forming a dummy gate stack over a channel region of the fin-shaped structure, recessing a source/drain region of the fin-shaped structure to form a trench, removing the sacrificial layers in the channel region to release the channel layers as channel members, forming a dielectric dummy layer filling space between the channel members, forming a source/drain feature in the trench, removing the dummy gate stack, removing the dielectric dummy layer to release the channel members, trimming the channel members to reduce a thickness of the channel members, and forming a gate structure to wrap around the channel members.

### PRIORITY DATA

This application claims priority to U.S. Provisional Patent Application No. 63/672,579 filed on Jul. 17, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. As GAA devices continue to scale, challenges have arisen. Although existing structure and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, and 35 illustrate fragmentary cross-sectional views of a work-in-progress (WIP) structure during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and manufacturing methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. Ideally, due to the different material compositions, a large etch selectivity between the sacrificial materials (e.g., SiGe) and the nanostructures (e.g., Si) should have safeguarded the nanostructures from etch loss during the removal of the sacrificial materials. However, atoms other than silicon (e.g., Ge) in the sacrificial materials may diffuse into the nanostructures as impurities during annealing processes, such as the annealing processes in forming shallow trench isolation (STI) feature and/or epitaxial source/drain features. The diffusion of the impurities lowers the etch selectivity. As a result, the nanostructures may suffer from etch loss during the removal of the sacrificial materials. Further, impurities diffusing into the crystalline lattice of the nanostructures can create lattice distortions due to the mismatch in atomic sizes, which may introduce strain and defects. These defects act as trap states within the bandgap, also known as interface traps. The interface traps can capture and release charge carriers, leading to fluctuations in the threshold voltage and deterioration of the device uniformity.

The present disclosure provides methods for forming a GAA transistor. In an example process, a fin-shaped structure with channel layers and sacrificial layers is formed over a substrate. Impurities (e.g., Ge) in the sacrificial layers may diffuse into surface portions of the channel layers. The surface portions of the channel layers may also be referred to as intermixing layers for having silicon and impurities other than silicon. Compared with the sacrificial layers that includes a relatively higher germanium concentration (also referred to as mole fraction or germanium atomic percentage (Ge %)), the intermixing layers have a relatively lower germanium concentration. After formation of a dummy gate stack over a channel region of the fin-shaped structure, at least one gate spacer is formed over the dummy gate stack. Source/drain regions of the fin-shaped structure are recessed. The sacrificial layers are removed to release the channel layers as channel members in a selective etching process. The selective etching process is tuned to have a high etch contrast between the sacrificial layers and the channel layers. Due to the difference in germanium concentration, the intermixing layers may remain in surface portions of the channel members. A dielectric dummy layer is then deposited to wrap around each of the channel members in a suitable deposition process, such as an atomic layer deposition (ALD) process. The dielectric dummy layer is then selectively and partially recessed to form inner spacer recesses between the plurality of channel members. An inner spacer layer is deposited over the inner spacer recesses. The deposited inner spacer layer is etched back to form inner spacer features. Source/drain features are then formed over the source/drain recesses. After selective removal of the dummy gate stack, the dielectric dummy layer is selectively removed to release the channel members again. The channel members are further trimmed to remove the intermixing layers to substantially eliminate interface traps introduced by the impurities. A gate structure is then formed to wrap around each of the channel members.

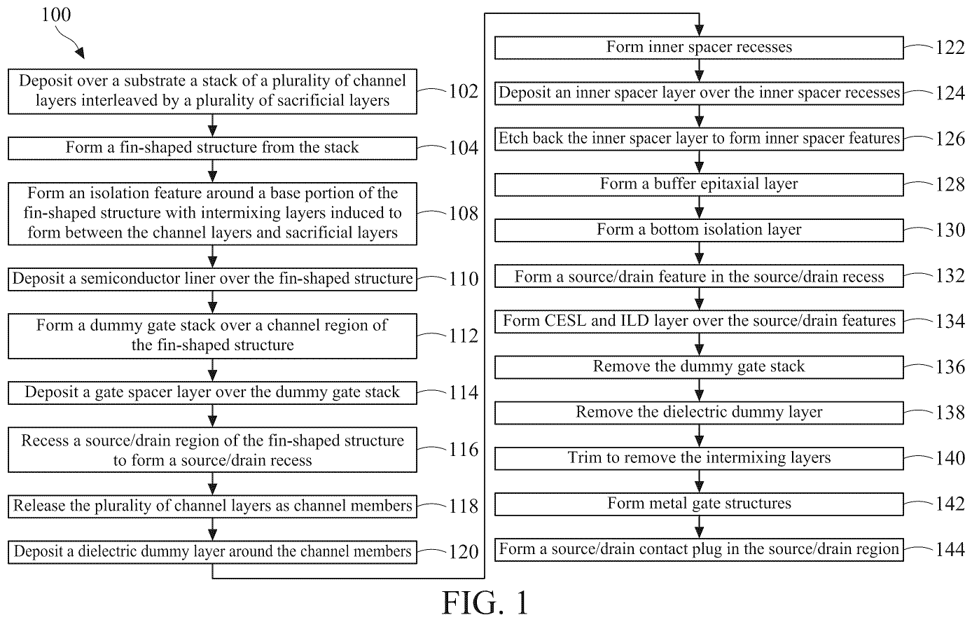

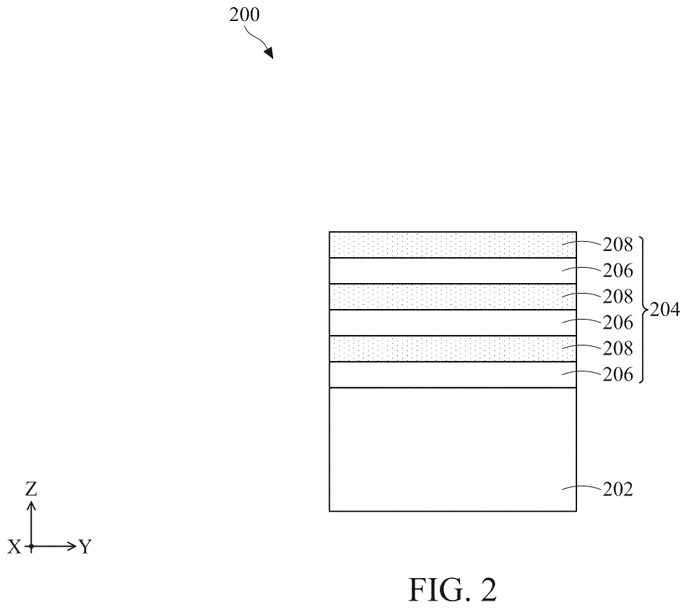

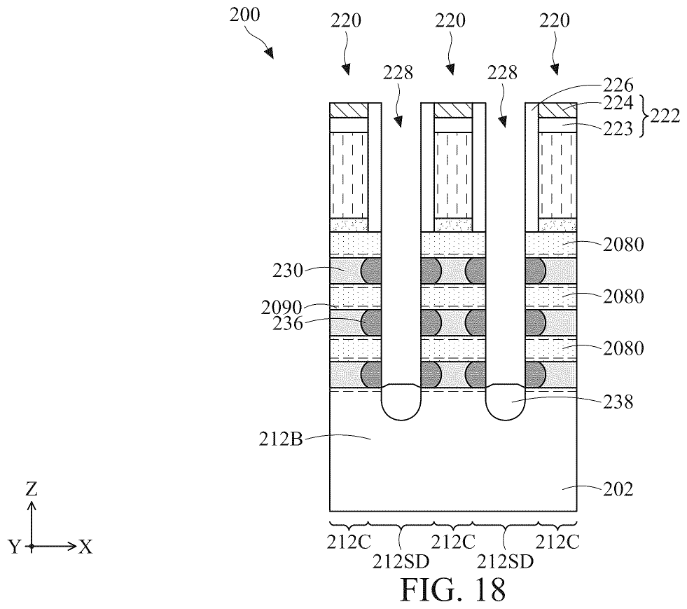

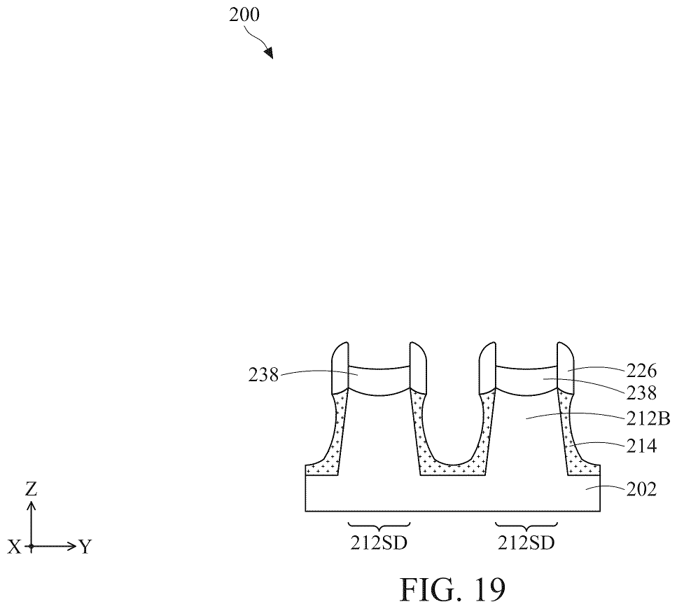

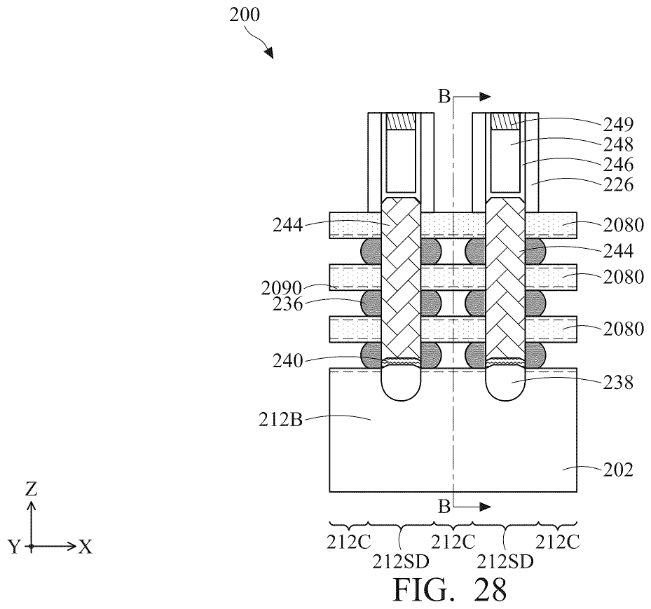

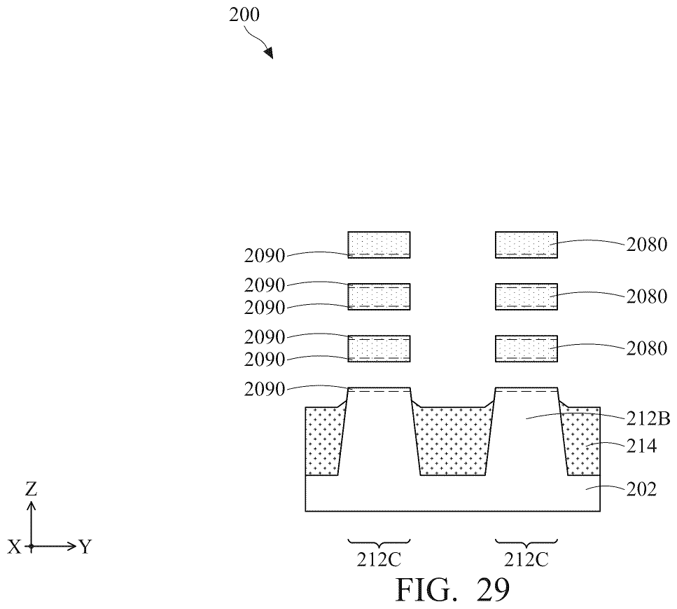

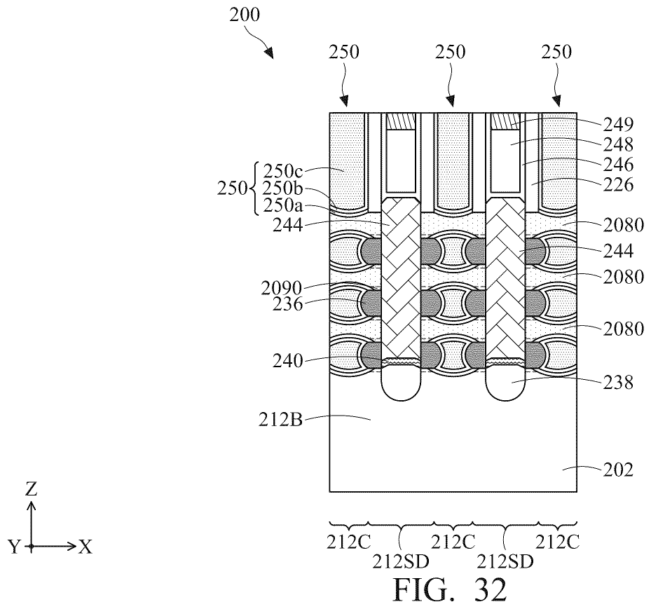

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-35, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-35 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the semiconductor device 200. As shown in FIG. 2, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, Ge % in the sacrificial layers 206 may be not less than about 20%, such as about 30% or above. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

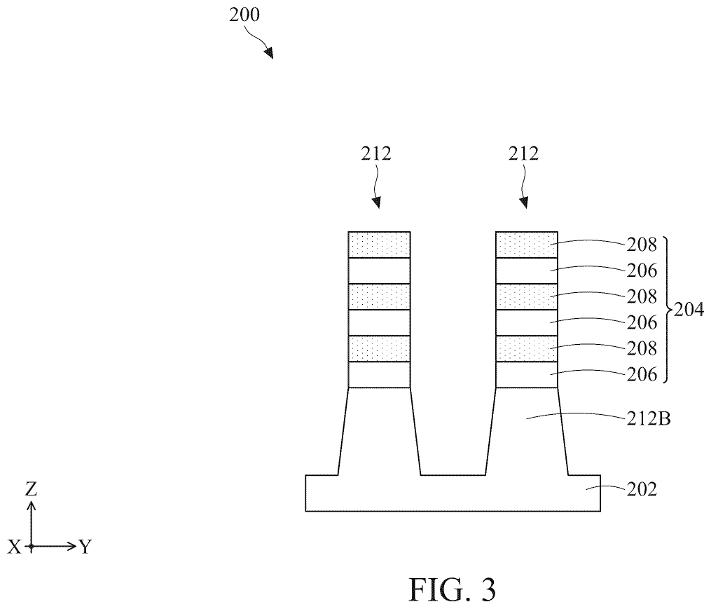

Referring to FIGS. 1 and 3, method 100 includes a block 104 where fin-shaped structures 212 are formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structures 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 3, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 extends vertically along the Z direction and lengthwise along the X direction. As shown in FIG. 3, the fin-shaped structure 212 includes a fin-shaped base 212B (or called based portion/protrusion) patterned from the substrate 202 and the patterned stack 204 disposed directly over the fin-shaped base 212B. In some instances, a width of the fin-shaped structures 212 measured along the Y direction may be between about 3 nm and about 20 nm.

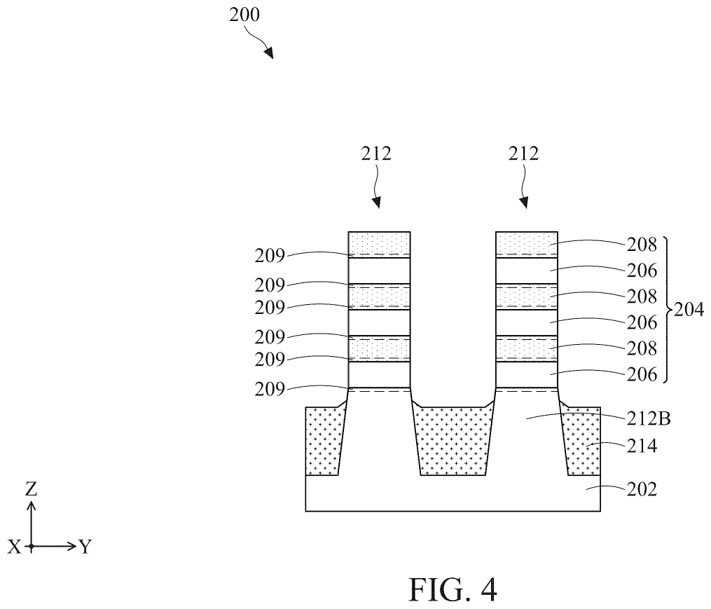

Referring to FIGS. 1 and 4, method 100 includes a block 108 where an isolation feature 214 is formed around the fin-shaped base 212B of the fin-shaped structures 212. In some embodiments represented in FIG. 4, the isolation feature 214 is disposed on sidewalls of the fin-shaped base 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 4. The fin-shaped structure 212 rises above the STI feature 214 after the recessing, while the STI feature 214 remains on sidewalls of the fin-shaped base 212B. In the illustrated embodiment, the top surface of the STI feature 214 has a dishing profile. A center point of the dishing profile of the STI feature 214 is below a top surface of the fin-shaped base 212B.

In some embodiments, the formation of STI feature 214 may include a thermal treatment to cure the dielectric material of the STI feature 214. The thermal treatment may promote germanium atoms in the sacrificial layers 206 to diffuse into adjacent channel layers 208, thereby inducing intermixing layers 209 between the adjacent ones of the channel layers 208 and the sacrificial layers 206, as shown in FIG. 4. An intermixing layer 209 is also formed between the bottommost sacrificial layer 206 and the top portion of the substrate 202. In some embodiments of method 100, a thermal treatment in the formation of STI feature 214 may be optional and/or skipped, and yet method 100 may still have one or more other thermal treatments in subsequent processes, such as during the formation of epitaxial source/drain features, to induce the intermixing layers 209. The thermal treatment accelerates the diffusion of germanium atoms from the sacrificial layers 206 into the channel layers 208 and thus forms the intermixing layers 209 therebetween. The intermixing layers 209 are rich in silicon and include a small portion of germanium. The Ge % in the intermixing layers 209 may be in a range between about 0.02% and about 5%, in some embodiments. The Ge % in the intermixing layers 209 is less than that in the sacrificial layers 206, for example, a ratio of the Ge % in the intermixing layers 209 and that of the sacrificial layers 206 ranging between about 1:100 and about 1:10. The thickness of the intermixing layers 209 may be in the range between about 0.1 nm and about 0.6 nm, in some embodiments.

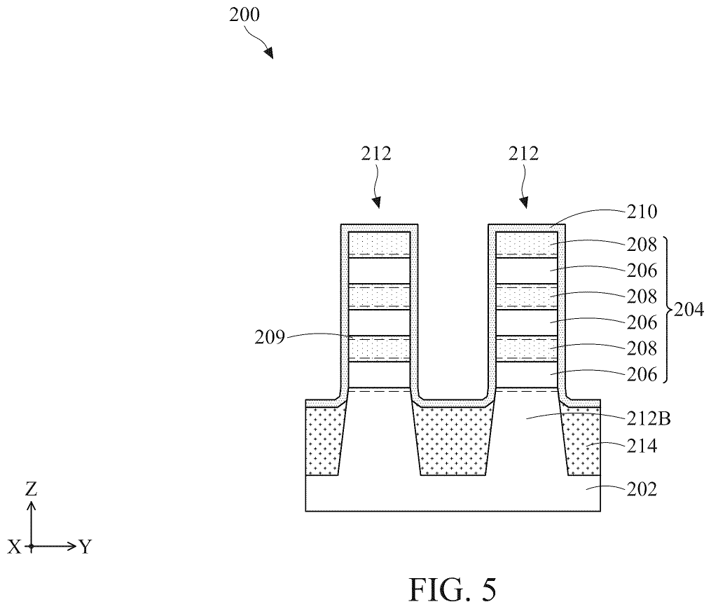

Referring to FIGS. 1 and 5, method 100 includes a block 110 where a semiconductor liner 210 is deposited over the fin-shaped structure 212. After the formation of the STI feature 214, the semiconductor liner 210 may be deposited over the semiconductor device 200, including over the STI feature 214, over a top surface of the fin-shaped structure 212, and along sidewalls of the fin-shaped structure 212. The semiconductor liner 210 functions to protect the sidewalls of the sacrificial layers 206 as it can sustain undesirable damages during the fabrication processes. In some embodiments, the semiconductor liner 210 may include silicon (Si). In some implementations, the semiconductor liner 210 may be deposited using PVD, CVD, or atomic layer deposition (ALD).

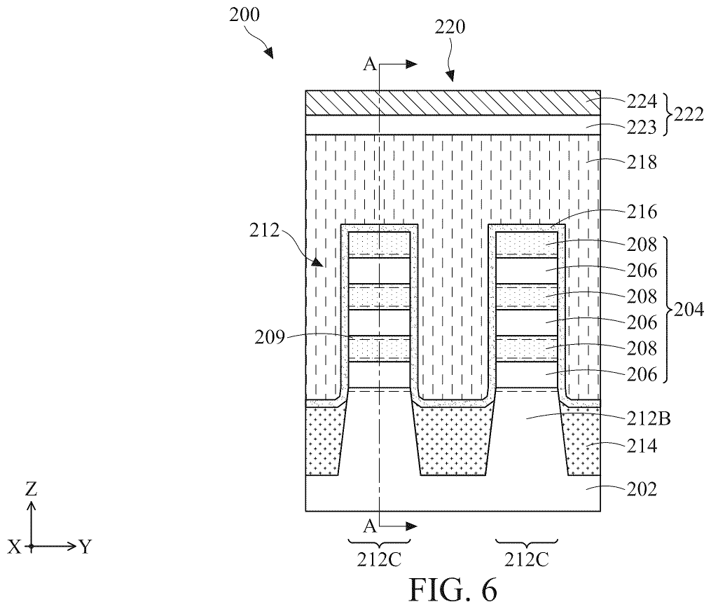

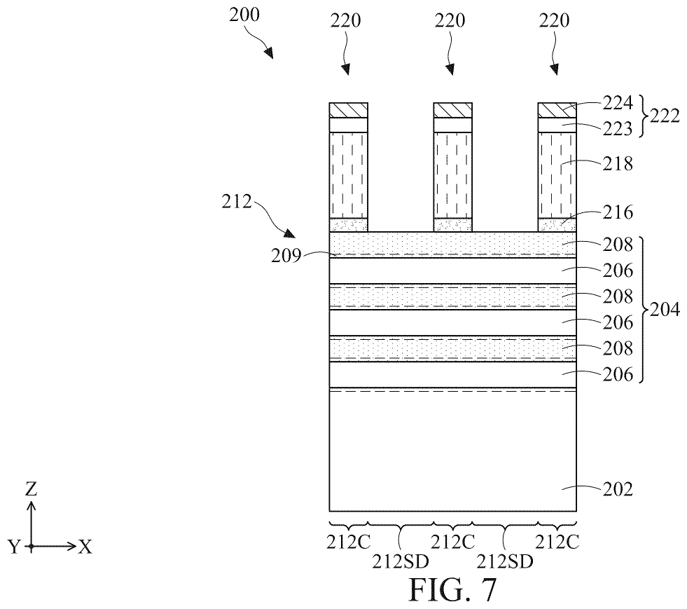

Referring to FIGS. 1 and 6-7, method 100 includes a block 112 where dummy gate stacks 220 are formed over a channel region 212C of the fin-shaped structure 212. The dummy gate stack 220 serves as a placeholder to undergo various processes and is to be removed and replaced by a functional gate structure. Other processes and configuration are possible. FIG. 7 is a cross-sectional view along the A-A line in FIG. 6. In some embodiments as illustrated in FIG. 7, the dummy gate stacks 220 are formed over the fin-shaped structure 212, and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 7, the channel region 212C is disposed between two source/drain regions 212SD along the X direction. As used herein, a source/drain region, or “S/D region,” may refer to a region that provides a source and/or drain for one or multiple devices. It may also refer to a source or a drain of one or multiple devices.

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be blanketly deposited over the semiconductor device 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 210 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 7. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 7, the dummy gate stack 220 is patterned such that it is only disposed over the channel region 212C, not disposed over the source/drain region 212SD.

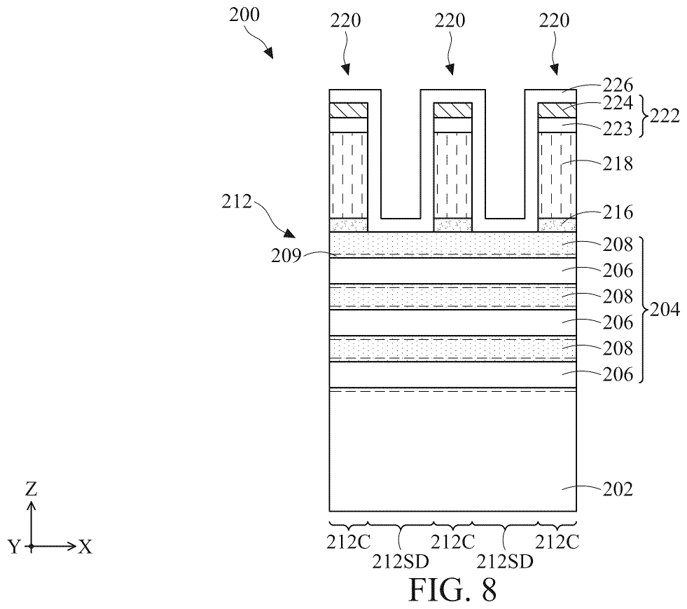

Referring to FIGS. 1 and 8, method 100 includes a block 114 where a gate spacer layer 226 is deposited over the semiconductor device 200, including over the dummy gate stack 220. In some embodiments, the gate spacer layer 226 is deposited conformally over the semiconductor device 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

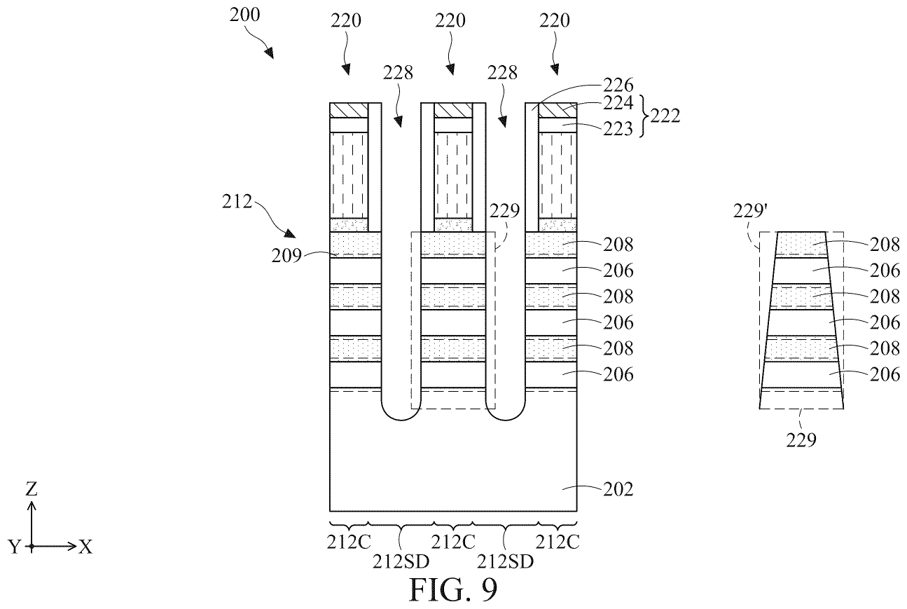

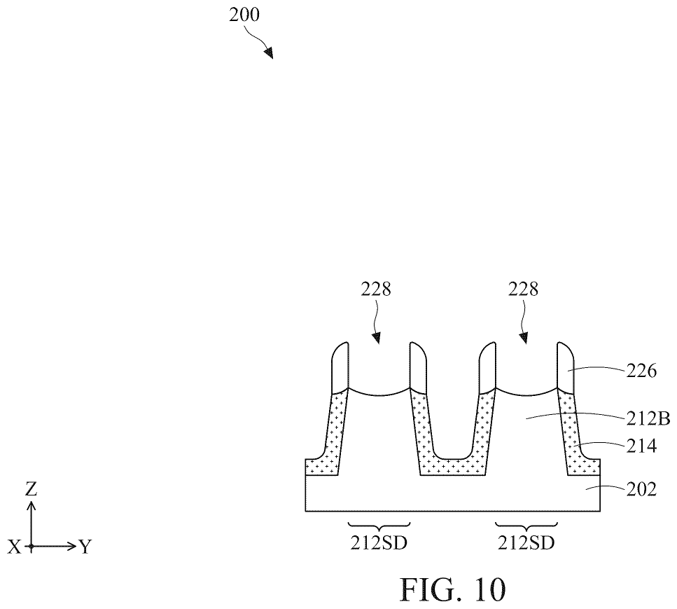

Referring to FIGS. 1 and 9-10, method 100 includes a block 116 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202. An example dry etching process for block 116 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 9, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Notably, although sidewalls of the sacrificial layers 206 and the channel layers 208 are illustrated as substantially vertical, in some embodiments the sidewalls may have a tapering profile (as shown in the region 229′ as an alternative embodiment of the region 229), such that the width of the channel layers 208 (and consequently width of the subsequently-formed dielectric dummy layer 230 and width of the subsequently-formed gate structure 250 in the space reserved by the sacrificial layers 206) as measured in the X direction gradually increases from top to bottom. Reference is made to FIG. 10, which includes a fragmentary cross-sectional view across two adjacent source/drain regions 212SD. As shown in FIG. 10, over the source/drain regions 212SD, the majority of the fin-shaped structure 212 is etched away and a top surface of the fin-shaped base 212B is exposed in the source/drain region 212SD. Because the gate spacer layer 226 is etched at a slower rate than the fin-shaped structure 212, the gate spacer layer 226 in the source/drain region 212SD rises above the top surface of the fin-shaped base 212B.

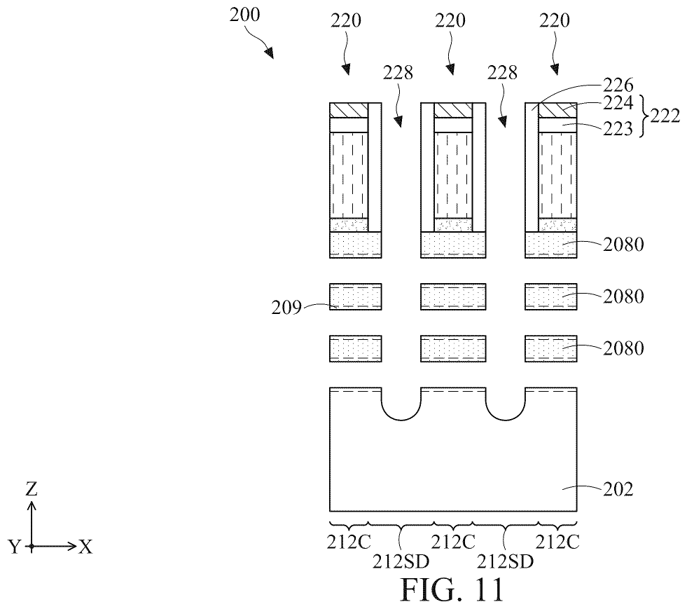

Referring to FIGS. 1 and 11, method 100 includes a block 118 where the plurality of channel layers 208 in the channel regions are released as channel members 2080. After the formation of the source/drain trenches 228, the sacrificial layers 206 interleaving the channel layers 208 in the channel region 212C are selectively removed. The selective removal of the sacrificial layers 206 releases the channel layers 208 to form channel members 2080. Depending on the design, the channel members 2080 may take form of nanowires, nanorods, nanosheets, or other nanostructures. The selective removal of the sacrificial layers 206 forms spaces between and around adjacent channel members 2080. The selective removal of the sacrificial layers 206 may be implemented by a selective dry etching process. An example selective dry etching process may include use of one or more fluorine-containing (F-containing) gas. In some embodiments, the fluorine-containing gas can include fluorine (F₂), hydrogen fluoride (HF), chlorine trifluoride (ClF₃), fluorine radical (F*), and nitrogen trifluoride radical (NF₃*). In some embodiments, the sacrificial layers 206 can be etched by a gas phase etching using fluorine-containing gases, such as F₂, HF, and ClF₃. In some embodiments, the sacrificial layers 206 can be etched by a radical phase etching using radicals, such as F*, H*, and NF₃*, generated from fluorine-containing gases by a remote plasma system. The dry etching process can have by-products, such as silicon tetrafluoride (SiF₄) and germanium tetrafluoride (GeF₄). In some embodiments, the fluorine-containing gases can have a flow rate ranging from about 100 standard cubic centimeter per minute (sccm) to about 500 sccm. In some embodiments, the dry etching process can be performed at a temperature from about −20° C. to about 150° C. under a pressure from about 100 mTorr to about 1000 mTorr. In some embodiments, the intermixing layers 209 substantially remain after the removal of the sacrificial layers 206 due to germanium concentration difference, and accordingly certain etch contrast, between the sacrificial layers 206 and the intermixing layers 209.

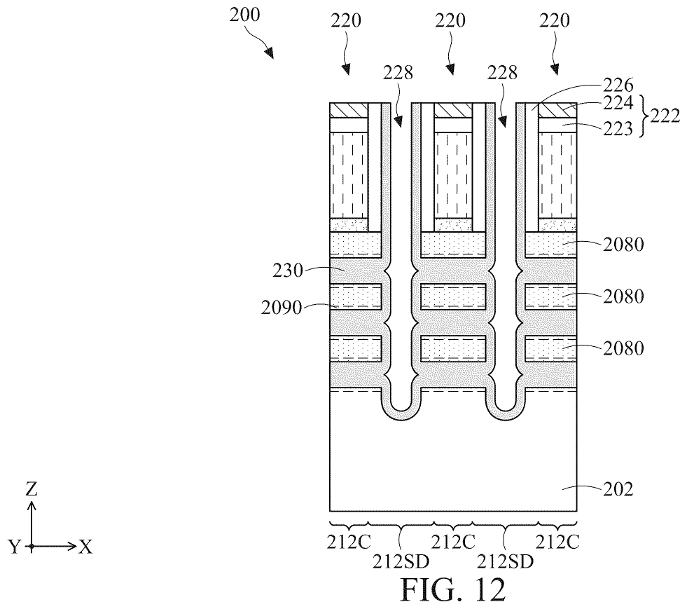

Referring to FIGS. 1 and 12, method 100 includes a block 120 where a dielectric dummy layer 230 is deposited around the channel members 2080 and over the source/drain trenches 228. The dielectric dummy layer 230 may be an oxide, such as silicon oxide in some embodiments, and may be deposited using ALD, flowable chemical vapor deposition (FCVD), plasma enhanced chemical vapor deposition (PECVD), or other suitable deposition processes. The dielectric dummy layer 230 fills the space among the channel members 2080 and covers sidewalls of the channel members 2080. In the illustrated embodiment, in order to improve the gap fill capability without leaving voids thereunder, the deposition of the dielectric dummy layer 230 may include an ALD process to first form a thin dielectric layer and a subsequent FCVD process to form a thick dielectric layer over the thin dielectric layer. The combination of the ALD and FCVD processes improves gap fill capability without compromising production throughput. Additionally, the intermixing layers 209 may be partially oxidized during the deposition of the oxide material of the dielectric dummy layer 230. The oxidation may be due to the intermixing layers 209 being exposed in an oxygen rich environment. As a result, the germanium containing intermixing layers 209 may be converted to a compound that includes a mixture of germanium-doped silicon (SiₘGeₙ) and silicon germanium oxide (Si_{1-x-y}GeₓO_{y}). In furtherance of some embodiments, the oxidation may occur to a shallow surface portion of the intermixing layer 209, which is converted to a thin film of silicon germanium oxide, while an inner portion of the intermixing layer 209 remains as germanium-doped silicon and substantially free of oxygen. The partially oxidized intermixing layers 209 are denoted as intermixing layers 2090 thereafter.

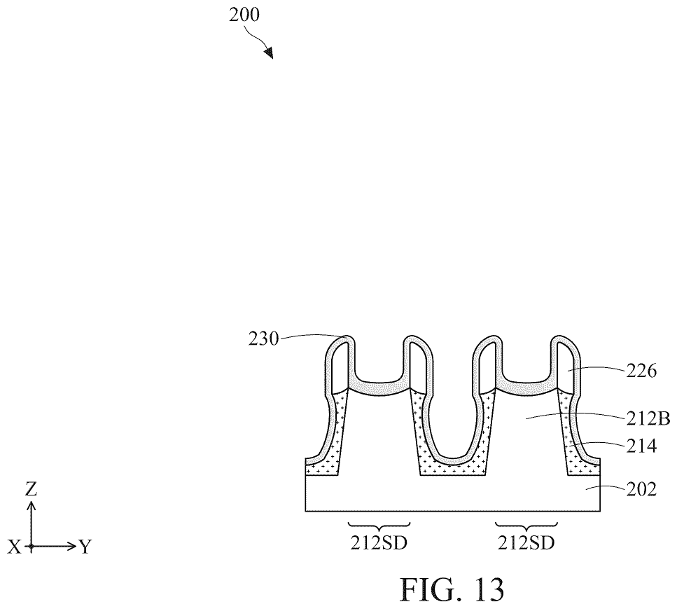

Reference is made to FIG. 13, which includes a fragmentary cross-sectional view across two adjacent source/drain regions 212SD. The dielectric dummy layer 230 extends over the isolation feature 214, sidewalls of the gate spacer layer 226, and top surfaces of the gate spacer layer 226. Due to the ALD process, a thickness of the dielectric dummy layer 230 at the bottom of the source/drain trench 228 may be substantially the same as a thickness of the dielectric dummy layer 230 along sidewalls of the gate spacer layer 226.

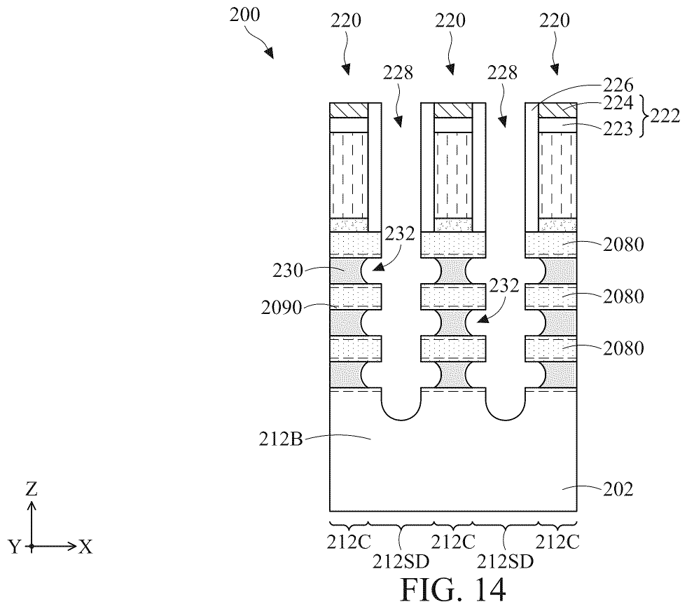

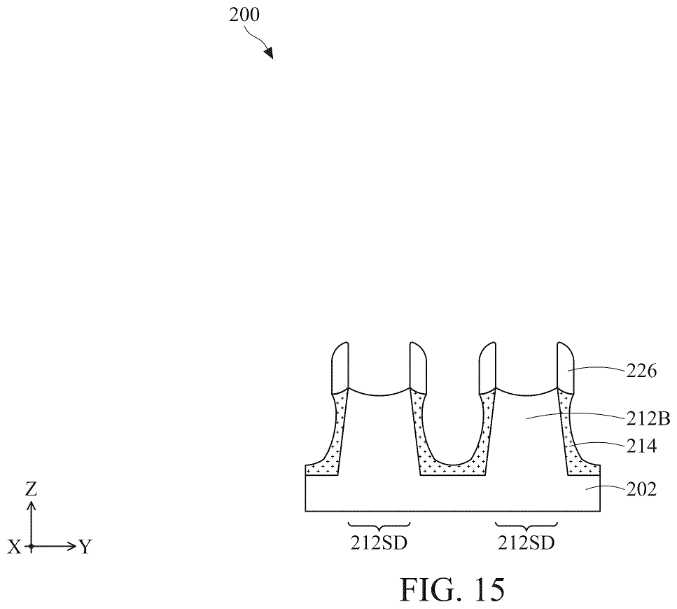

Referring to FIGS. 1 and 14-15, method 100 includes a block 122 where inner spacer recesses 232 are formed. Referring to FIG. 14, the dielectric dummy layers 230 are selectively and partially recessed to form inner spacer recesses 232. The inner spacer recesses 232 may have a concave profile bending away from the source/drain trenches 228. In an embodiment, the selective recess of the dielectric dummy layer 230 may be performed using a selective wet etching process or a selective dry etching process. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As shown in FIG. 15, the dielectric dummy layer 230 is removed from the source/drain regions 212SD, and the fin-shaped base 212B is exposed.

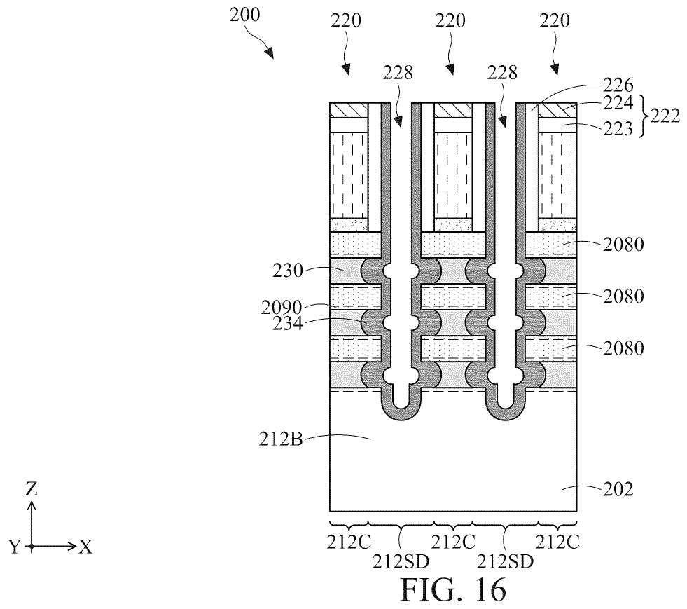

Referring to FIGS. 1 and 16, method 100 includes a block 124 where an inner spacer layer 234 is deposited over the inner spacer recesses 232. A composition of the inner spacer layer 234 is different from a composition of the dielectric dummy layer 230 to ensure that each one of them may be selectively etched without substantially damaging the other one. In some embodiments, the inner spacer layer 234 may include silicon carbonitride (SiCN), silicon oxycarbonitride (SiOCN), silicon nitride (SiN), silicon oxycarbide (SiOC), or silicon oxynitride (SiON). In some implementations, the inner spacer layer 234 may be deposited using CVD or ALD.

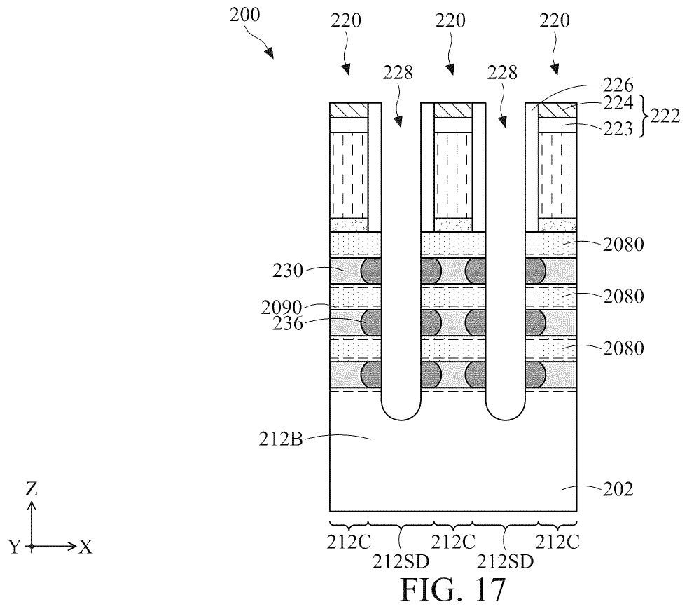

Referring to FIGS. 1 and 17, method 100 includes a block 126 where the inner spacer layer 234 is etched back to form inner spacer features 236 over the inner spacer recesses 232. In some embodiments, the etching back at block 124 may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacer features 236 laterally extend to a position directly under the dummy gate stack 220. Alternatively, the inner spacer features 236 may substantially remain under the gate spacer layer 226 without extending to a position directly under the dummy gate stack 220. Notably, the formation of the inner spacer features 236, including manufacturing steps at blocks 122-126, may be optional. That is, the formation of the inner spacer features 236 may be omitted, and the inner spacer features 236 may not exist in the final structure, in some embodiments.

Referring to FIGS. 1 and 18-19, method 100 includes a block 128 where a separation layer (or separating layer) 238 is deposited in the bottom of the source/drain trenches 228. In some embodiments, the separation layer 238 is a buffer epitaxial layer epitaxially grown from the top surface of the fin-shaped base 212B. By way of example, epitaxial growth of the buffer epitaxial layer 238 may be performed by VPE, ultra-high vacuum CVD (UHV-CVD), MBE, and/or other suitable epitaxial grow processes. In some embodiments, the buffer epitaxial layer 238 includes the same material as the substrate 202, such as silicon. In some alternative embodiments, the buffer epitaxial layer 238 includes a different semiconductor material other than silicon, such as SiGe, SiSn, or other suitable semiconductor material. In some embodiments, the buffer epitaxial layer 238 is dopant-free, where for example, no intentional doping is performed during the epitaxial growth process. As a comparison, in one instance, the substrate 202 is lightly doped and has a higher doping concentration than the buffer epitaxial layer 238. The separation layer 238 provides a high resistance path from the S/D regions to the semiconductor substrate, such that the leakage current in the semiconductor substrate is suppressed. Notably, the formation of the separation layer 238, including manufacturing steps at block 128, may be optional. That is, the formation of the separation layer 238 may be omitted, and the separation layer 238 may not exist in the final structure, in some embodiments.

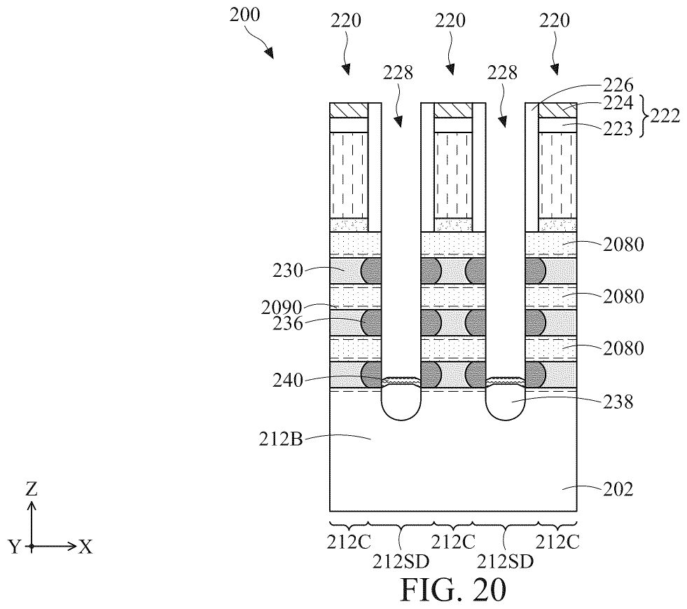

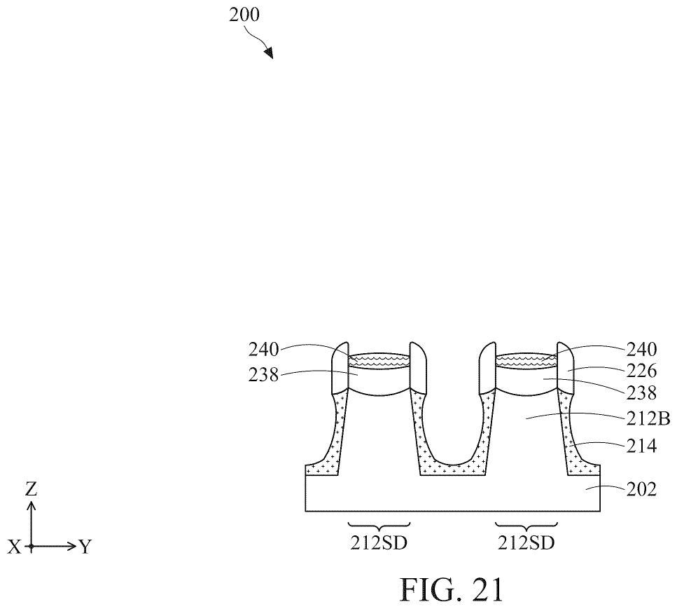

Referring to FIGS. 1 and 20-21, method 100 includes a block 130 where a bottom isolation layer 240 is formed over the separation layer 238 (or on the substrate 202 if the formation of the separation layer 238 is omitted). Because the bottom isolation layer 240 may interface source/drain features and oxygen content may oxidize source/drain features, the bottom isolation layer 240 may be formed of an oxygen-free dielectric material, such as nitrogen. In an example process, a chlorine-containing silicon nitride layer is deposited over the source/drain trenches 228, including over a top surface of the buffer epitaxial layer 238. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etching process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etching process etches the chlorine-containing silicon nitride along sidewalls faster than it does relatively chlorine-free silicon nitride layer at the bottom of the source/drain trenches 228, the bottom isolation layer 240 may be formed over the buffer epitaxial layer 238, as shown in FIGS. 20 and 21. Notably, the formation of the bottom isolation layer 240, including manufacturing steps at block 130, may be optional. That is, the formation of the bottom isolation layer 240 may be omitted, and the bottom isolation layer 240 may not exist in the final structure, in some embodiments.

Referring to FIGS. 1 and 22-23, method 100 includes a block 132 where a source/drain feature 244 is formed over the source/drain region 212SD. While not explicitly shown, before any of the epitaxial layers are formed, method 100 may include a cleaning process to clean surfaces of the semiconductor device 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, a sulfuric peroxide mixture, or hydrofluoric acid for oxide removal. The dry clean process may include helium (He) and hydrogen (H₂) treatment.

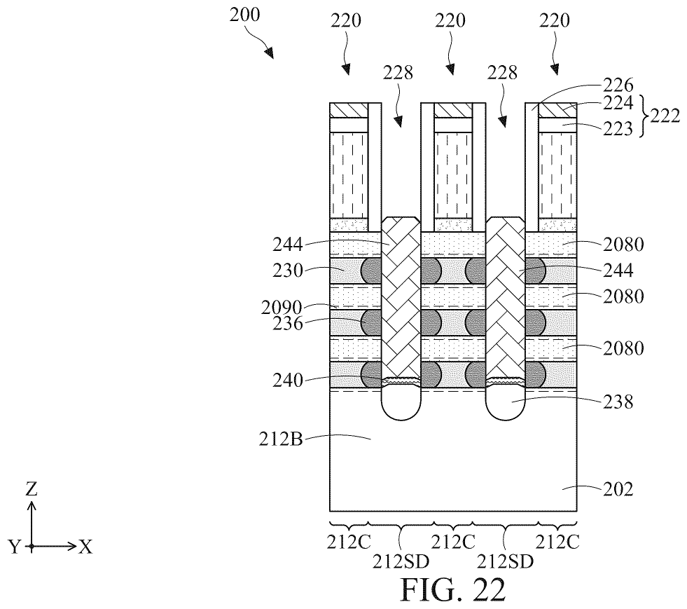

Reference is made to FIG. 22. The source/drain feature 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. While not explicitly shown in the figures, in some embodiments, the source/drain feature 244 may include multiple layers. For example, the source/drain feature 244 may include a lightly doped epitaxial feature over the bottom isolation layer 240 and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping.

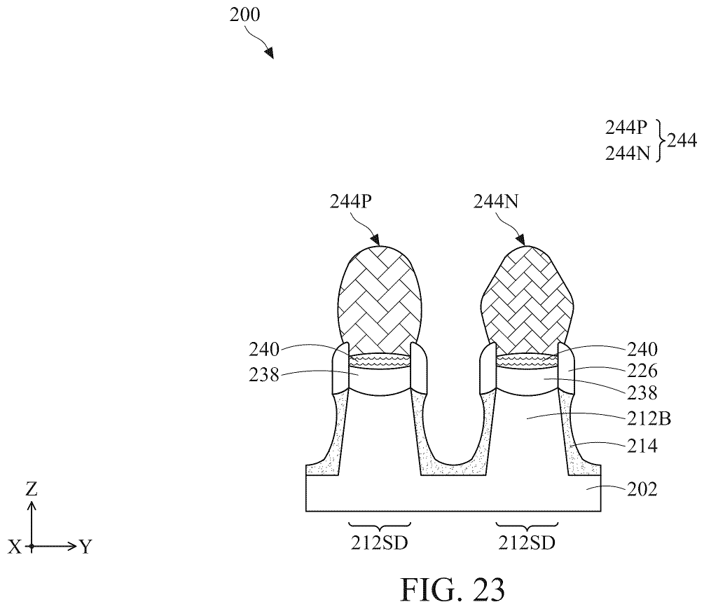

Reference is made to FIG. 23, which includes a fragmentary cross-sectional view across two adjacent source/drain regions 212SD. In some embodiments represented in FIG. 23, an n-type source/drain feature 244N may be adjacent to a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). Each of the n-type source/drain feature 244N and the p-type source/drain feature 244P may be in direct contact with a top surface of the bottom isolation layer 240. For ease of illustration and description, the n-type source/drain feature 244N and the p-type source/drain feature 244P may be collectively referred to as the source/drain feature 244, as in FIG. 22.

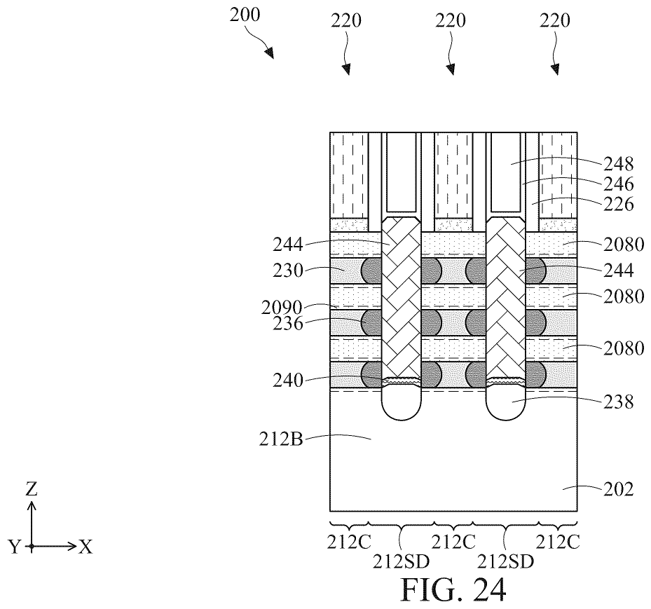

Referring to FIGS. 1 and 24-25, method 100 includes a block 134 where a contact etch stop layer (CESL) 246, an interlayer dielectric (ILD) layer 248, and a capping layer 249 are deposited in the source/drain regions 212SD. As shown in FIG. 24, the CESL 246 is deposited over the source/drain feature 244. The CESL 246 may include silicon nitride or aluminum nitride. In some implementations, the CESL 246 may be deposited using CVD or ALD. The ILD layer 248 is then deposited over the CESL 246. In some embodiments, the ILD layer 248 includes materials such as silicon oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process.

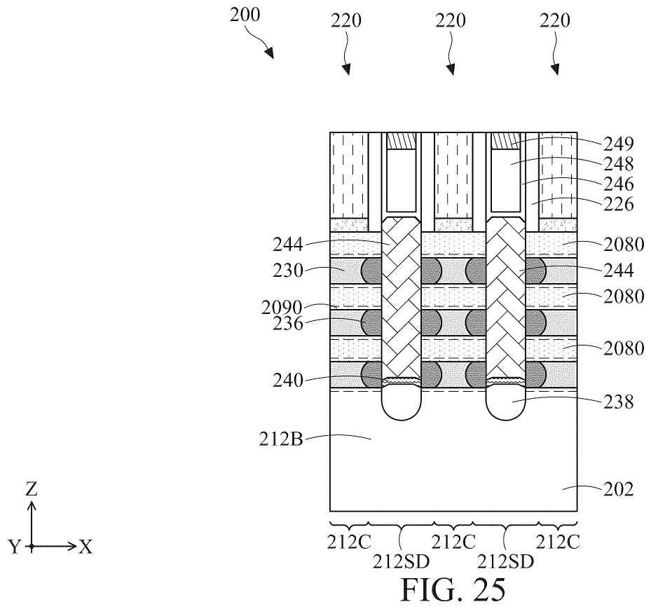

Referring to FIG. 25, in order to protect the ILD layer 248 from being damaged during the dielectric dummy layer 230 removal step, the ILD layer 248 is selectively recessed to form a top recess and a capping layer 249 is formed over the top recess. The capping layer 249 is formed of a different material than the dielectric dummy layer 230. When the dielectric dummy layer 230 includes silicon oxide, the capping layer 249 is not formed of silicon oxide so as to ensure etch selectivity. In some embodiments, the capping layer 249 may include silicon nitride, silicon carbonitride, silicon carbide, or silicon oxycarbonitride. In one embodiment, the capping layer 249 may include silicon nitride. Another planarization is performed to remove excess capping layer 249 and to expose the dummy gate stack 220. After the planarization, top surfaces of the capping layer 249, the CESL 246, the gate spacer layer 226, and the dummy gate stacks 220 are coplanar.

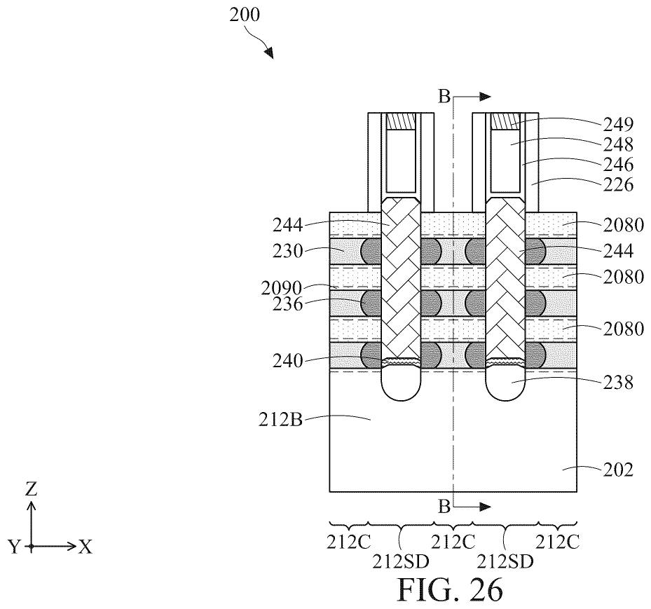

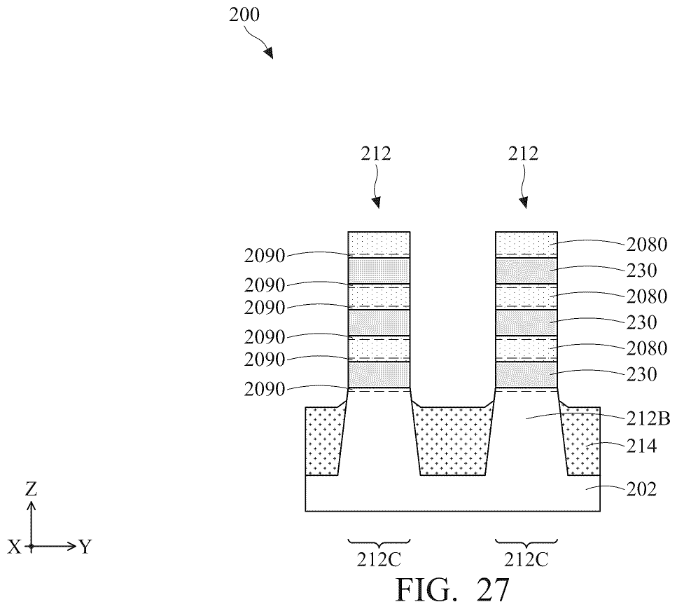

Referring to FIGS. 1 and 26-27, method 100 includes a block 136 where the dummy gate stacks 220 are selectively removed. FIG. 27 is a cross-sectional view in the channel region 212C, which is along the B-B line in FIG. 26. The exposure of the dummy gate stack 220 at the conclusion of operations at block 134 allows the removal thereof. The removal of the dummy gate stack 220 may include one or more etching processes that are selective to the materials of the dummy gate stack 220. For example, the removal of the dummy gate stack 220 may be performed using a selective wet etch, a selective dry etch, or a combination thereof that is selective to the dummy gate stack 220. The removal of the dummy gate stack 220 forms a gate trench that exposes the stack of the channel members 2080 and the dielectric dummy layer 230.

Referring to FIGS. 1 and 28-29, method 100 includes a block 138 where the dielectric dummy layer 230 is selectively removed from the channel regions 212C. After the removal of the dummy gate stack 220, the dielectric dummy layer 230 in the channel regions 212C is exposed and subsequently removed in a separate etching process. For example, a selective wet etching process or a selective dry etching process may be performed to remove the dielectric dummy layer 230. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the selective removal of the dielectric dummy layer 230, the intermixing layers 2090 in the channel regions 212C are exposed. In some embodiments, the removal of the dielectric dummy layer 230 also removes the oxidized surface portion of the intermixing layers 2090, due to limited etch contrast between the oxidized surface portion of the intermixing layers 2090 and the dielectric dummy layer 230 that both include oxide. The inner portion of the intermixing layers 2090, which is mainly a semiconductor material (germanium-doped silicon) other than an oxide, is exposed.

Referring to FIGS. 1 and 30-31, method 100 includes a block 140 where a trimming process is performed to remove the intermixing layers 2090 from the channel regions 212C. The trimming process may use any suitable etching process such as dry etching, wet etching, and/or RIE. In one example, the trimming process is a wet etching process using an etchant consisting of NH₄OH, H₂O₂, and H₂O. A ratio of NH₄OH:H₂O₂ in the etchant may range from about 5:100 to about 20:100. The trimming process may be carried out at a room temperature or slightly elevated temperatures, such as from about 25° C. to about 60° C., for a duration from about 20 seconds to about 100 seconds in some embodiments.

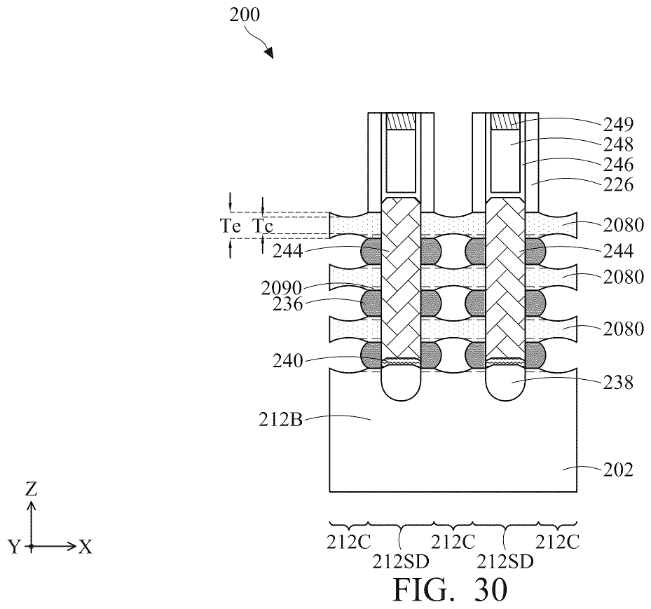

In addition to removing the intermixing layers 2090 from the channel regions 212C, the trimming process also slightly removes a surface portion of the suspended channel members 2080 exposed in the channel regions 212C. This occurs due to the limited etch contrast between the intermixing layers 2090 and the channel members 2080, as silicon is the primary constituent of both. The removal of the intermixing layers 2090 and the surface portion of the channel members 2080 may result in curvature (also referred to as concave or dishing) top and bottom surfaces of the channel members 2080. Referring to FIG. 30, the thickness of the channel members 2080 measured at a center position of the respective channel region 212C (denoted as Tc) is smaller than the thickness measured at an end portion of the channel members 2080 (denoted as Te). Further, in some embodiments, the inner spacer features 236 may also experience etch loss during the trimming process, becoming thinner in the X direction. For example, the inner spacer features 236 may become thinner than the gate spacer layer 226 measured in the X direction. In furtherance of some embodiments, the outer sidewalls of the inner spacer features 236 facing the gate trench may transition from bending towards the gate trench, as depicted in FIG. 30, to bending towards the epitaxial source/drain feature 244 due to the etch loss. In some alternative embodiments, material of the inner spacer features 236 may exhibit high etching selectively and substantially remain intact during the removing of the intermixing layers 2090, such that the inner spacer features 236 may have the same thickness as the gate spacer layer 226 as measured in the X direction, or even thicker due to the bending sidewalls of the inner spacer features 236 facing the gate trench (as depicted in FIG. 30). Notably, the trimming process leaves the end portions of the channel members 2080 and the end portions of the intermixing layer 2090 substantially unetched, which are under protection of the gate spacer layer 226. In other words, end portions of the intermixing layers 2090 vertically stacked between the inner spacer features 236 and the channel members 2080, as well as between the bottommost inner spacer feature 236 and the substrate 202, remain after the trimming process.

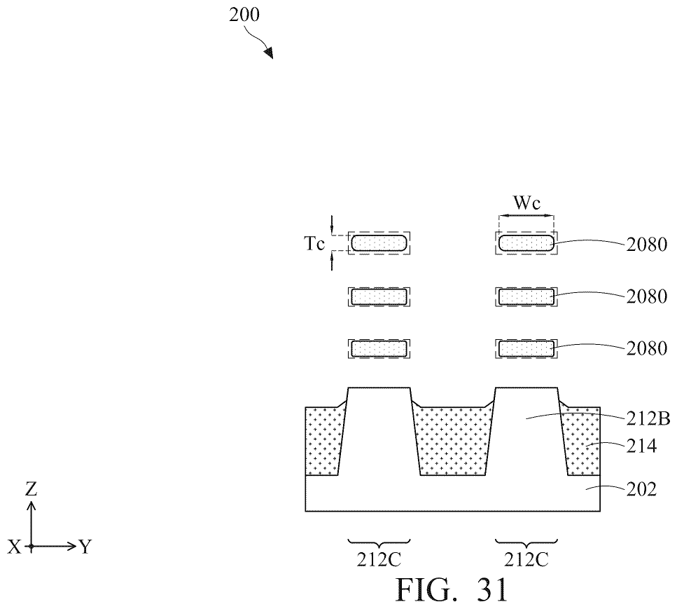

FIG. 31 keeps dashed rectangular boxes to represent the contours of the combination of the remaining end portions of the channel members 2080 and the intermixing layer 2090 directly under the gate spacer layer 226. The dashed rectangular boxes also aid visual comparison of the trimmed dimensions of the center portions of the channel members 2080. The center portions of the channel members 2080 have dimensions reduced in both the horizontal direction and vertical direction in the Y-Z plane. In the vertical direction, the thickness of the channel members 2080 (Tc) is reduced by about 4% to about 30%, such as about 0.2 nm to about 1.2 nm in some embodiments, compared to the dashed rectangular box, and the width of the channel members 2080 (Wc) is reduced by about 2% to about 8%, such as about 0.5 nm to about 1.5 nm in some embodiments. The reduction as in nanometers measured in the horizontal direction may be larger than the reduction in the vertical direction, which may be due to a higher etch rate at the crystalline surface (e.g., a (110) surface) exposed on sidewalls of the channel members 2080 than at the different crystalline surface (e.g., a (100) surface) exposed on top and bottom surfaces of the channel members 2080. Further, the topmost channel member 2080 may experience greater etch loss than the underlying ones due to more direct exposure to the etchant. Consequently, the width (Wc) and thickness (Tc) of the topmost channel member 2080 may be smaller than those of the channel members beneath it. The bottommost channel member 2080 may have the largest width (Wc) and thickness (Tc), with the dimensions of the intermediate channel members gradually transitioning between those of the topmost and bottommost channel members. Still further, the corners of the channel members 2080 may become rounded due to the trimming process. The topmost channel member 2080 may exhibit more rounded corners than those beneath it, while the bottommost channel member 2080 may have the least rounded corners, closest to a right angle. The corners of the intermediate channel members 2080 gradually transition between those of the topmost and bottommost channel members.

Referring back to FIG. 30, regarding the topmost channel member 2080, the remaining end portion of the intermixing layer 2090 is under its bottom surface and not on its top surface. The remaining end portions of the intermixing layers 2090 also directly interfaces sidewalls of the source/drain feature 244 and the buffer epitaxial layer 238. The intermixing layers 2090 include a mixture of germanium-doped silicon (SiₘGeₙ) and silicon germanium oxide (Si_{1-x-y}GeₓO_{y}), such as an inner portion germanium-doped silicon and a surface layer of silicon germanium oxide. In some embodiments, n is in a range between about 0.02% and about 5%, n is less than m (n<m), x is in a range between about 0.01% and about 3%, y is in a range between about 1% to about 30%, and x is less than y (x<y). In the illustrated embodiment, the length of the remaining end portions of the intermixing layers 2090 measured in the X direction is smaller than the thickness of the inner spacers features 236 measured in the X direction. The thickness of the intermixing layers 2090 measured in the Z direction may be in the range between about 0.1 nm and about 0.6 nm, in some embodiments. In some embodiments, the bottommost one of the intermixing layers 209 is thick enough to have physical contact with either the buffer epitaxial layer 238 or the bottom isolation layer 240. In some embodiments, the bottommost one of the intermixing layers 209 is thick enough to have physical contact with both of the buffer epitaxial layer 238 and the bottom isolation layer 240.

Referring to FIGS. 1 and 32-33, method 100 includes a block 142 where after the release of the channel members 2080, a gate structure 250 is formed to wrap around each of the channel members 2080. The gate structure 250 is also referred to as metal gate structure 250 due to its metal-containing layers. The isolation feature 214 is disposed alongside the channel members 2080. The gate structure 250 is disposed over the channel members 2080. The gate structure 250 includes an interfacial layer, a gate dielectric layer over the interfacial layer, and at least one metal layer over the gate dielectric layer. The interfacial layer interfaces the channel members 2080. The gate dielectric layer and the isolation feature 214 intermix at an interface between the gate dielectric layer and the isolation feature.

In the depicted embodiment, the gate structure 250 includes an interfacial layer 250a interfacing the channel members 2080 and the substrate 202 in the channel region 212C, a high-k dielectric layer 250b over the interfacial layer 250a, and a gate electrode layer 250c over the high-k dielectric layer 250b. The interfacial layer 250a and the high-k dielectric layer 250b may be collectively referred to as the gate dielectric layer. The interfacial layer 250a may include a dielectric material such as silicon oxide, hafnium silicate, or silicon oxynitride. The interfacial layer 250a may be formed by chemical oxidation, thermal oxidation, atomic layer deposition (ALD), chemical vapor deposition (CVD), and/or other suitable method. The high-k dielectric layer 250b may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer 250b may be formed by ALD, physical vapor deposition (PVD), CVD, oxidation, and/or other suitable methods. The interfacial layer 250a may directly interface the remaining portion of the intermixing layer 2090. Depending on the thickness of the intermixing layer 2090 and the interfacial layer 250a, the high-k dielectric layer 250b may also directly interface the remaining portion of the intermixing layer 2090.

The gate electrode layer 250c of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 250c may include titanium nitride (TiN), titanium aluminum (TiAl), titanium aluminum nitride (TiAIN), tantalum nitride (TaN), tantalum aluminum (TaAl), tantalum aluminum nitride (TaAIN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 250c may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C.

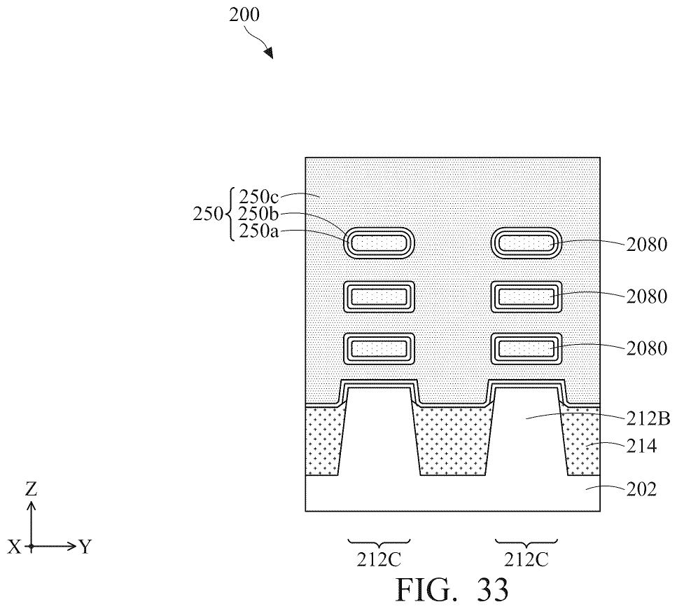

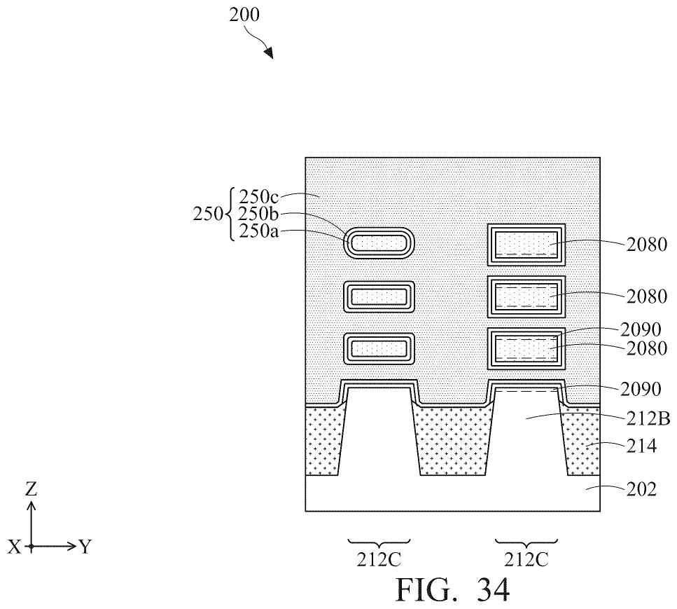

Referring to FIG. 33, the transistors formed on the depicted two channel regions 212C may have opposite conductivity types, such as one n-type transistor and one p-type transistor. Accordingly, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080. The depicted embodiment in FIG. 33 has the trimming process at block 140 applied in both the n-type and p-type device regions, such that no intermixing layer 2090 would remain in the two depicted channel regions 212C. Alternatively, the trimming process at block 140 may be applied to one of the regions, such as depicted in FIG. 34. In FIG. 34, the trimming process at block 140 is applied to the channel region 212C positioned on the left, which may be an n-type device region, and the intermixing layer 2090 remains in the other channel region 212C position on the right, which may be a p-type device region as opposite to the conductivity type on the left. Alternatively, the trimming process at block 140 is applied to the channel region 212C positioned on the left, which may be a p-type device region, and the intermixing layer 2090 remains in the other channel region 212C position on the right, which may be an n-type device region as opposite to the conductivity type on the left. The channel members 2080 in the right channel region 212C are also wider and thicker than their counterparts in the left channel regions 212C as skipping the trimming process.

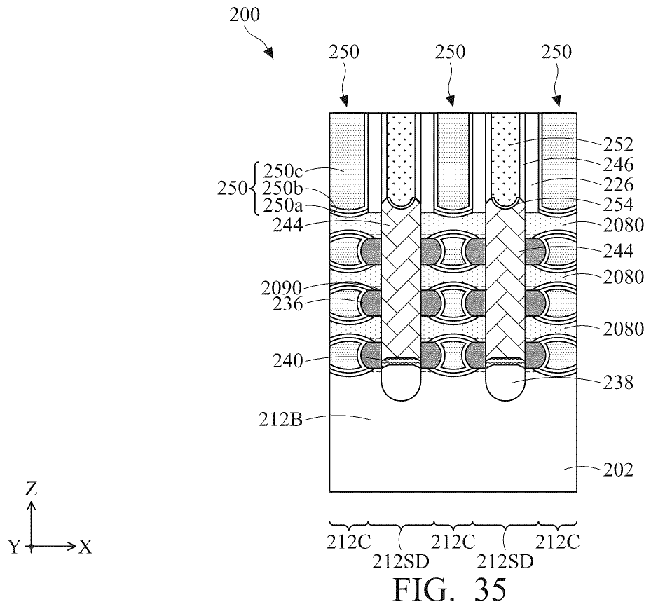

Referring to FIGS. 1 and 35, method 100 includes a block 144 where source/drain contact plugs 252 and optional silicide features 254 between the source/drain contact plugs 252 and the source/drain feature 244 are formed in the source/drain regions 212SD. In an exemplary process, contact holes are first formed by etching through the capping layer 249, the ILD layer 248, and the CESL 246. The etching process may be a self-aligned process such that the capping layer 249 and the ILD layer 248 are removed using the vertical sidewalls of the CESL 246 as an etch stop layer. An upper portion of the source/drain feature 244 may optionally be etched to have a concave shape as a bottom of the contact hole. In the depicted embodiment, the source/drain feature 244 is recessed to a position below the bottom surface of the topmost channel member 2080. The silicide features 254 are formed at the bottom of the contact holes. The silicide features 254 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. Subsequently, source/drain contact plugs 252 are formed on the silicide features 254. Each source/drain contact plug 252 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAIN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes. The silicide feature 254 and the source/drain contact plug 252 may be collectively referred to as the source/drain contact.

Although not intended to be limiting, embodiments of the present disclosure provide one or more of the following advantages. For example, embodiments of the present disclosure replace germanium-containing sacrificial layers with oxide-containing dielectric dummy layers and perform an extra trimming process to further remove germanium residue in the channel region after the dielectric dummy layers are selectively removed to release the channel members. A metal gate structure is then formed to wrap around each of the channel members. Such a process reduces germanium atoms as impurities in the channel region and improves the performance uniformity of GAA transistors. Further, embodiments of the present disclosure can be readily integrated into existing semiconductor manufacturing processes.

In one exemplary aspect, the present disclosure is directed to a method. The method includes forming over a substrate a stack that includes a plurality of channel layers interleaved by a plurality of sacrificial layers, patterning the stack to form a fin-shaped structure, forming an isolation feature on sidewalls of the fin-shaped structure, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench, removing the sacrificial layers in the channel region to release the channel layers as channel members, depositing a dielectric dummy layer filling space between the channel members, forming a source/drain feature in the source/drain region, after the forming of the source/drain feature, removing the dummy gate stack, removing the dielectric dummy layer to release the channel members, after the removing of the dielectric dummy layer, trimming the channel members to reduce a thickness of the channel members in the channel region, and forming a gate structure to wrap around each of the channel members. In some embodiments, the trimming of the channel members also reduces a width of the channel members in the channel region. In some embodiments, a reduction of the width of the channel members is more than a reduction of the thickness of the channel members. In some embodiments, the trimming of the channel members removes a germanium-containing surface portion from the channel members. In some embodiments, a concentration of germanium in the germanium-containing surface portion is in a range from about 0.02% to about 5%. In some embodiments, the germanium-containing surface portion is formed during the forming of the isolation feature. In some embodiments, the germanium-containing surface portion is formed during the forming of the source/drain feature. In some embodiments, after the trimming of the channel members, end portions of a germanium-containing surface portion of the channel members remain under the gate spacer layer. In some embodiments, the method further includes laterally recessing the dielectric dummy layer to form inner spacer recesses, depositing an inner spacer layer over the inner spacer recesses, and etching back the inner spacer layer to form inner spacer features in the inner spacer recesses. The trimming of the channel members also reduces a thickness of the inner spacer features. In some embodiments, the trimming of the channel members forms a dishing profile of top and bottom surfaces of the channel members. In some embodiments, a top surface of the isolation feature has a dishing profile.

In another exemplary aspect, the present disclosure is directed to a method. The method includes forming over a substrate a fin-shaped structure that includes a plurality of silicon layers interleaved by a plurality of silicon germanium layers. A plurality of intermixing layers that contain germanium-doped silicon are formed between adjacent two of the silicon layers and the silicon germanium layers. The method also includes forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench, selectively removing the silicon germanium layers in the channel region to expose the intermixing layers, depositing an oxide layer in space among the silicon layers, forming a source/drain feature in the source/drain trench, removing the dummy gate stack, selectively removing the oxide layer, removing the intermixing layers from the channel region, and forming a gate structure to wrap around each of the silicon layers. In some embodiments, the intermixing layers include a germanium concentration less than that of the silicon germanium layers. In some embodiments, the depositing of the oxide layer oxidizes the intermixing layers. In some embodiments, the selectively removing of the oxide layer also removes an oxidized portion of the intermixing layers. In some embodiments, the removing of the intermixing layers reduces a thickness and a width of the silicon layers in a cross section perpendicular to a lengthwise direction of the silicon layers. In some embodiments, the removing of the intermixing layers forms a dishing profile of top and bottom surfaces of the silicon layers in a cross section along a lengthwise direction of the silicon layers. In some embodiments, the removing of the intermixing layers includes a wet etching process.

In yet another exemplary aspect, the present disclosure is directed to a semiconductor structure. The semiconductor structure includes a plurality of nanostructures suspended above a substrate, a gate structure wrapping around each of the nanostructures, a gate spacer layer disposed on sidewalls of the gate structure, a source/drain feature abutting the nanostructures, inner spacer features interposed between the gate structure and the source/drain feature, and a germanium-containing intermixing layer vertically stacked between the inner spacer features and the nanostructures. In some embodiments, the germanium-containing intermixing layer includes an inner portion of silicon germanium and an outer portion of silicon germanium oxide. In some embodiments, top and bottom surfaces of the nanostructures have a dishing profile.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes a plurality of channel layers interleaved by a plurality of sacrificial layers;
patterning the stack to form a fin-shaped structure;
forming an isolation feature on sidewalls of the fin-shaped structure;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench;
removing the sacrificial layers in the channel region to release the channel layers as channel members;
depositing a dielectric dummy layer filling space between the channel members;
forming a source/drain feature in the source/drain region;
after the forming of the source/drain feature, removing the dummy gate stack;
removing the dielectric dummy layer to release the channel members;
after the removing of the dielectric dummy layer, trimming the channel members to reduce a thickness of the channel members in the channel region; and
forming a gate structure to wrap around each of the channel members.

2. The method of claim 1, wherein the trimming of the channel members also reduces a width of the channel members in the channel region.

3. The method of claim 2, wherein a reduction of the width of the channel members is more than a reduction of the thickness of the channel members.

4. The method of claim 1, wherein the trimming of the channel members removes a germanium-containing surface portion from the channel members.

5. The method of claim 4, wherein the germanium-containing surface portion is formed during the forming of the isolation feature.

6. The method of claim 4, wherein the germanium-containing surface portion is formed during the forming of the source/drain feature.

7. The method of claim 1, wherein after the trimming of the channel members, end portions of a germanium-containing surface portion of the channel members remain under the gate spacer layer.

8. The method of claim 1, further comprising:
laterally recessing the dielectric dummy layer to form inner spacer recesses;
depositing an inner spacer layer over the inner spacer recesses; and
etching back the inner spacer layer to form inner spacer features in the inner spacer recesses,
wherein the trimming of the channel members also reduces a thickness of the inner spacer features.

9. The method of claim 1, wherein the trimming of the channel members forms a dishing profile of top and bottom surfaces of the channel members.

10. The method of claim 1, wherein a top surface of the isolation feature has a dishing profile.

11. A method, comprising:
forming over a substrate a fin-shaped structure that includes a plurality of silicon layers interleaved by a plurality of silicon germanium layers, wherein a plurality of intermixing layers that contain germanium-doped silicon are formed between adjacent two of the silicon layers and the silicon germanium layers;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench;
selectively removing the silicon germanium layers in the channel region to expose the intermixing layers;
depositing an oxide layer in space among the silicon layers;
forming a source/drain feature in the source/drain trench;
removing the dummy gate stack;
selectively removing the oxide layer;
removing the intermixing layers from the channel region; and
forming a gate structure to wrap around each of the silicon layers.

12. The method of claim 11, wherein the intermixing layers include a germanium concentration less than that of the silicon germanium layers.

13. The method of claim 11, wherein the depositing of the oxide layer oxidizes the intermixing layers.

14. The method of claim 13, wherein the selectively removing of the oxide layer also removes an oxidized portion of the intermixing layers.

15. The method of claim 11, wherein the removing of the intermixing layers reduces a thickness and a width of the silicon layers in a cross section perpendicular to a lengthwise direction of the silicon layers.

16. The method of claim 11, wherein the removing of the intermixing layers forms a dishing profile of top and bottom surfaces of the silicon layers in a cross section along a lengthwise direction of the silicon layers.

17. The method of claim 16, wherein the removing of the intermixing layers includes a wet etching process.

18. A semiconductor structure, comprising:
a plurality of nanostructures suspended above a substrate;
a gate structure wrapping around each of the nanostructures;
a gate spacer layer disposed on sidewalls of the gate structure;
a source/drain feature abutting the nanostructures;
inner spacer features interposed between the gate structure and the source/drain feature; and
a germanium-containing intermixing layer vertically stacked between the inner spacer features and the nanostructures.

19. The semiconductor structure of claim 18, wherein the germanium-containing intermixing layer includes an inner portion of silicon germanium and an outer portion of silicon germanium oxide.

20. The semiconductor structure of claim 18, wherein top and bottom surfaces of the nanostructures have a dishing profile.
